(19) United States
(12) Patent Application Publication
(10) Pub. No.: US 2006/0084249 A1
(43) Pub. Date: Apr. 20, 2006

(54) Method for manufacturing a hybrid semiconductor wafer having a buried oxide film

(75) Inventor: Takashi Yamada, Ebina-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/097,166

(22) Filed: Apr. 4, 2005

(30) Foreign Application Priority Data
Oct. 19, 2004 (JP) 2004-304555

(51) Int. Cl. H01L 21/425

(52) U.S. Cl. 438/526; 438/770; 438/766

(57) ABSTRACT

A method for manufacturing a hybrid semiconductor wafer having a BOX film, includes: depositing a first masking film on a silicon based substrate; depositing a second masking film on the first masking film; forming a window portion having a perpendicular sidewall by selectively removing a part of the second masking film; removing a part of the first masking film selectively; implanting oxidizing species into the substrate through the window portion; removing the second masking film; and forming a BOX film in the substrate, and forming a thermal oxide film in the substrate.

### CROSS REFERENCE TO RELATED APPLICATIONS AND INCORPORATION BY REFERENCE

This application is based upon and claims the benefit of priority from the prior Japanese Patent Applications No. P2004-304555, filed on Oct. 19, 2004; the entire contents of which are incorporated herein by reference.

### BACKGROUND OF THE INVENTION

1. Field of the Invention

The present invention relates to a method for manufacturing a hybrid semiconductor wafer, and, more particularly, relates to a method for manufacturing a hybrid semiconductor wafer including both a Silicon-On-Insulator (SOI) area and a bulk area.

2. Description of the Related Art

A hybrid semiconductor wafer which combines a SOI area and a bulk area is proposed for a system on a chip (SOC). The use of the hybrid semiconductor wafer can provide a SOI structured device and a bulk structured device on a single chip. For example, applications such as a high-performance embedded DRAM chip, which combines high-performance CMOS logic having SOI structure and a large-capacity DRAM having a bulk structure on a single chip, can be provided.

Partial SOI structure by Separation by Implantation of Oxygen (SIMOX) technology is proposed for a method of manufacturing the hybrid semiconductor wafer. In the patterned SIMOX technology, a masking film of silicon oxide (SiO₂) or the like is deposited on a part of a surface of a semiconductor substrate made of single-crystalline silicon or the like. Then oxygen ions (O⁺), which are used as an oxidizing species, are implanted in the semiconductor substrate using the masking film as a mask. After the masking film is removed, annealing accompanied by oxidizing ambient annealing is performed. As a result, a buried oxide (BOX) film (BOX layer) is formed using the reaction between the oxidizing species (O) and the silicon (Si) of the semiconductor substrate. Subsequently, a thermal oxide film, which was formed on the surface of the semiconductor substrate, is removed. According to the patterned SIMOX technology, only a masking film deposition process is added to the SIMOX technology, which is an established SOI substrate fabricating technology. Therefore it is possible to easily provide the hybrid semiconductor wafer at low-cost.

In the patterned SIMOX technology, it is necessary to form perpendicular side faces of the masking film, to planarize the BOX film at the edge in the SOI area. In order to form the perpendicularly shaped side faces of the masking film, Reactive Ion Etching (RIE) process is generally used. However, there are concerns about disparities in thickness of the SOI layer and deterioration of surface planarity of the semiconductor substrate, due to crystal lattice defects and/or contaminants by plasma damage in the RIE process and to over-etching for the semiconductor substrate respectively. Moreover, the horizontal level of the surface in the SOI area can become higher than the horizontal level of the surface of the bulk area due to volume expansion of the BOX formation. As a result, a level discrepancy is generated at the surface being formed with devices. Because of the level discrepancy, the margins in lithographic processing and etching process are decreased, and thereby the manufacturing yield is decreased.

As a method for improving the level discrepancy, a technique has been proposed to form an oxide film on a surface of a bulk area of a semiconductor substrate during high temperature annealing. However, the thickness of the oxide film that is required to adjust the level discrepancy is extremely thin (e.g. approximately 200 nm) compared with the thickness (e.g. approximately 1000 nm) of the masking film for oxygen ion implantation. Therefore it is necessary to make the masking film thinner before the high temperature annealing, or to further deposit another oxide film after the masking film is completely removed. However, in the case where the masking film is made thinner, it is difficult to control over the remaining oxide film thickness. Alternatively, in the case of further depositing another oxide film, there is a problem of increasing cost due to an increase in the number of processes by the addition of a further deposition process and by increasing the processes to ensure alignment between the additional oxide film and the patterns of the original SOI area and the bulk area.

### SUMMARY OF THE INVENTION

An aspect of the present invention inheres in a method for manufacturing a hybrid semiconductor wafer having a buried oxide film, including: depositing a first masking film on a silicon based substrate; depositing a second masking film on the first masking film; forming a window portion having a perpendicular sidewall by selectively removing a part of the second masking film; removing a part of the first masking film selectively using the second masking film as a mask; implanting oxidizing species into the substrate through the window portion using the first masking film and the second masking film as masks;

removing the second masking film; and forming a BOX film in the substrate by reaction between the oxidizing species and the silicon, and forming a thermal oxide film in the substrate, by annealing in an oxidizing ambient.

### BRIEF DESCRIPTION OF DRAWINGS

FIG. 1 is a cross-sectional view of a semiconductor wafer according to an embodiment of the present invention.

FIGS. 2 to 6 are cross-sectional views for explaining a method for manufacturing the semiconductor wafer according to the embodiment of the present invention.

FIG. 7 is a graph showing relation between height of SOI area and proper thickness of masking film according to the embodiment of the present invention.

FIGS. 8 to 13 are cross-sectional views for explaining the method for manufacturing of the semiconductor wafer according to a first modification of the present invention.

FIGS. 14 to 17 are cross-sectional views for explaining the method for manufacturing of the semiconductor wafer according to a second modification of the present invention.

FIGS. 18 to 21 a r e cross-sectional views for explaining the method for manufacturing of the semiconductor wafer according to third and fourth modifications of the present invention.

FIG. 22 is a cross-sectional view for explaining the method for manufacturing a semiconductor wafer according to a fifth modification of the present invention.

FIG. 23 is a cross-sectional view for explaining the method for manufacturing a semiconductor wafer according to a sixth modification of the present invention.

FIGS. 24 to 26 are cross-sectional views for explaining the method for manufacturing a semiconductor wafer according to a first comparative example.

FIGS. 27 to 29 are cross-sectional views for explaining the method for manufacturing a semiconductor wafer according to a second comparative example.

### DETAILED DESCRIPTION OF THE INVENTION

An embodiment of the present invention with various modifications will be described with reference to the accompanying drawings. It is to be noted that the same or similar reference numerals are applied to the same or similar parts and elements throughout the drawings, and the description of the same or similar parts and elements will be omitted or simplified.

Generally and as it is conventional in the representation of semiconductor devices, it will be appreciated that the various drawings are not drawn to scale from one figure to another nor inside a given figure, and in particular that the layer thickness are arbitrarily drawn for facilitating the reading of the drawings.

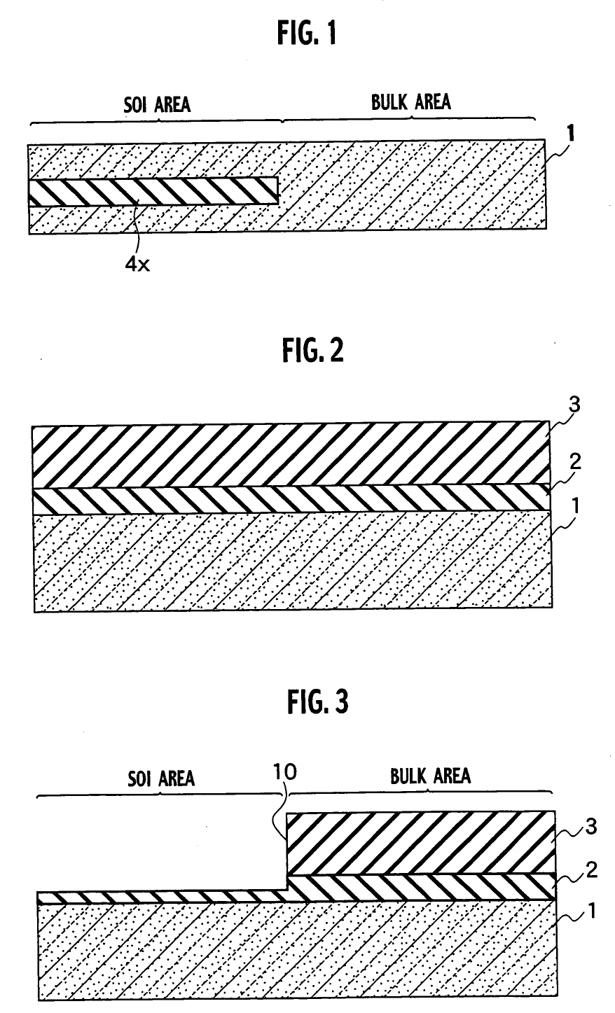

As shown in FIG. 1, a semiconductor wafer according to an embodiment of the present invention includes: a semiconductor substrate 1 having a SOI area surface, and a bulk area surface having a horizontal level substantially equal to the surface level in the SOI area. A buried oxide film (BOX film) 4x is embedded in the middle of the surface in the SOI area of the semiconductor substrate 1. In other words, the semiconductor wafer shown in FIG. 1 is a hybrid wafer combining a SOI area and a bulk area. In the SOI area, a logic circuit and the like, for example, a MOS transistor having a SOI structure can be disposed. In the bulk area, a DRAM cell and peripheral circuits and the like can be provided.

A material that includes Si, such as Single crystal silicon (Si), polycrystalline silicon, silicon germanium (SiGe), silicon carbide (SiC) or the like can be adapted as the semiconductor substrate 1. Silicon oxide (SiO₂) can be employed as a material of a BOX film 4x. The thickness of the BOX film 4x and an SOI layer from the semiconductor substrate 1 above the BOX film 4x may be set in accordance with the intended usage. For example, a thickness of the BOX film 4x is approximately 0.05 μm to 0.5 μm for use as a logic circuit in the generation of 130-nm minimum feature size, and the thickness of the SOI layer is approximately 0.05 μm to 0.3 μm. Here, the horizontal level of the surfaces of the bulk area and SOI area on the semiconductor substrate 1 are substantially equivalent to each other, and the surfaces of the bulk area and the SOI area are planarized.

Next, a method for manufacturing the semiconductor wafer, using patterned SIMOX technology according to the embodiment of the present invention, will be described referring to FIGS. 1 to 6. The manufacturing method described below is one example, and it is feasible to realize modifications by various other manufacturing methods.

First, as shown in FIG. 2, a Si based semiconductor substrate 1, such as a single crystal Si, a polycrystalline Si, SiGe, or SiC, is prepared. Then, a first masking film 2 such as a silicon oxide (SiO₂) film and the like is deposited on the semiconductor substrate 1 by chemical vapor deposition (CVD) or thermal oxidation so that the thickness of the first masking film 2 is approximately 200 nm. The first masking film 2 permits diffusion of an oxidizing species such as O and water vapor (H₂O). A second masking film 3 is deposited on the first masking film 2 by CVD so that the thickness of the second masking film 3 is approximately 1000 nm. As for the second masking film 3, a film which can be processed by RIE using the first masking film 2 as an etching stopping layer and selectively removed without inflicting to the surfaces of the first masking film 2 and the semiconductor substrate 1, is preferable. For example, when the semiconductor substrate 1 is made from single crystal Si and the first masking film is an SiO₂ film, it is acceptable for the material of the second masking film 3 to be silicon nitride (SiN), borosilicate glass (BSG), boron phosphorous silicate glass (BPSG) and the like.

Next, a resist film is coated on the second masking film 3, and then the resist film is patterned by lithography technology. Using the patterned resist film as a mask, a part of the second masking film 3 in the SOI area is selectively removed by RIE or the like. At this time, the amount of over-etching for the first masking film 2 is controlled within the scope of the thickness of the first masking film 2 by optimizing an etch selectivity and etching time. Consequently, it is possible to prevent RIE damage to the semiconductor substrate 1. For example, in a case where the semiconductor substrate 1 is a single crystal Si, the first masking film 2 is an SiO₂ film that has a thickness of 200 nm, and the second masking film 3 is a SiN film, a BSG film, a BPSG film or the like that has a thickness of 1000 nm, it is possible to remove the second masking film 3 without exposing the surface of the semiconductor substrate 1 by adjusting the time of RIE. The remaining resist film is removed by ashing, or the like. As a result, as shown in FIG. 3, a window portion 10 having perpendicular sidewalls is formed in the SOI area. When the second masking film 3 is etched by RIE, the perpendicular sidewalls of the window portion 10 can have a tapered shape having a steep incline of 85° C.

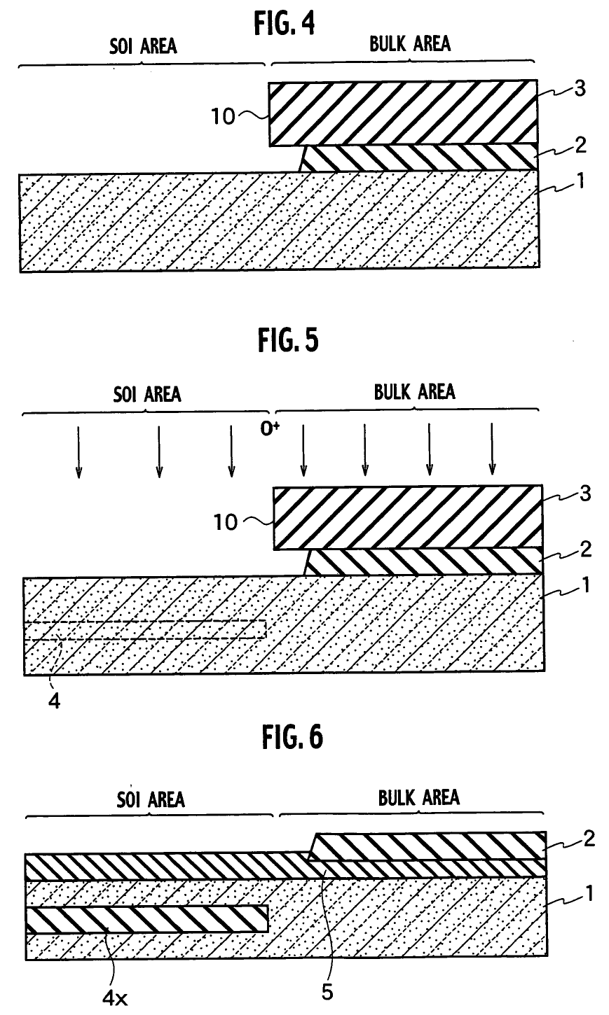

Next, an exposed portion of the first masking film 2 is selectively removed by wet etching, preferably so as not to protrude from an edge of the second masking film 3, as shown in FIG. 4. Here, wet etching, vapor etching, or dry etching is preferably used, since it is possible to maintain an etching selectivity between the first masking film 2 and the second masking film 3 and to protect the surface of the semiconductor substrate 1 from damage and contamination. Wet etching, vapor etching and dry etching are basically isotropic etching. The method suitable for film configuration is selected from among wet etching, vapor etching and dry etching. For example, when the first masking film 2 is SiO₂ and the second masking film 3 is SiN or BSG, wet etching using a buffered hydrofluoric acid solution (BHF), which is a mixture of ammonium fluoride (NH₄F) and hydrofluoric acid (HF), is used. Consequently, the first masking film 2 can be receded without inflicting heavy damage to the semiconductor substrate 1. Moreover, the amount of isotropic etching, such as wet etching, is controlled, and thereby it is possible to adjust the positional relationships between the edges of the second masking film 3 and the edges of the first masking film 2, which easily adjust the shape of the semiconductor wafer near the boundary, such as the thickness of the SOI layer and the BOX film.

Next, as shown in FIG. 5, using the second masking film 3 as a mask, oxygen ions (O⁺), which become oxidizing species, are implanted through the window portion 10 to the semiconductor substrate 1 in the SOI area. Consequently, an implantation area 4 is formed in the semiconductor substrate 1. In general SIMOX process, when a thin SOI layer of approximately 100 nm thickness is formed, the bulk area is sufficiently masked if the thickness of the second masking film is approximately 1000 nm. Thereafter, the second masking film 3 is removed by use of heated phosphoric acid (H₃PO₄) or HF vapor. If the second masking film 3 is a SiN film, H₃PO₄ is used; and if the second masking film 3 is a BSG film, HF vapor is used. In this manner, it is possible to remove the second masking film 3 with high selectivity, toward the semiconductor substrate 1 and the first masking film 2. Accordingly, it is possible to prevent damage to the semiconductor substrate 1 and the first masking film 2 when the second masking film 3 is removed.

Next, in a state where the first masking film 2 in the bulk area remains, in an oxidizing ambient, thermal process (high temperature annealing) is performed at approximately 1300 to 1400° C. As a result, a BOX film 4x is formed by the reaction of the oxidizing species (O) of the implantation area 4 in the SOI area and the Si of the semiconductor substrate 1, as shown in FIG. 6. The surface of the semiconductor substrate 1 in the SOI area expands due to volume expansion when the BOX film 4x is formed. At the same time, as shown in FIG. 6, a thermal oxide film 5 is formed on the surface of the semiconductor substrate 1 by the oxidizing species, in the oxidizing ambient. In the SOI area, the supply of the oxidizing species to the surface of the semiconductor substrate 1 is sufficient to make a thin oxide film on the surface just as in a normal oxidation process. The oxidation of the surface of the semiconductor substrate 1 proceeds by reaction-controlled mechanisms, at a steady oxidation rate. Along with increasing the thickness of the oxide film, the phenomenon of diffusion of the oxidizing species into the oxide film gradually becomes dominant. In the diffusion-controlled mechanism, the oxidation rate has a tendency to decrease in inverse proportion to the square root of the amount of diffusion time. On the other hand, in the bulk area, oxidation conditions are determined by diffusion-controlled mechanism at an earlier stage (or at the beginning of oxidation) since the first mask 2 is above the semiconductor substrate 2. Thus, in contrast to the SOI area, the oxidation of the surface of the semiconductor substrate 1 is restrained.

Here, the thickness of the first masking film 2 is adjusted so that the depth of the semiconductor substrate 1 underneath the first masking film 2 in the bulk area encroached by oxidation is thinner than the depth of the semiconductor substrate 1 in the SOI area encroached by the oxidation, by a thickness corresponding to volume expansion of the semiconductor substrate 1 due to the BOX formation. Accordingly, it is possible to substantially equalize the horizontal levels of the surface of the semiconductor substrate 1 in the SOI area and the surface of the semiconductor substrate 1 underneath the first masking film 2 in the bulk area. Note that it is preferable to set the thickness of the first masking film 2 and to set the conditions of the high temperature annealing so that oxidation of the semiconductor substrate 1 underneath the first masking film 2 starts with the diffusion-controlled mechanism. Therefore, it is possible to provide excellent control over the differentials of the levels, and to prevent unevenness of the amounts of oxidation of the surface of the semiconductor substrate 1 in the bulk area. Then, the first masking film 2 and the thermal oxide film 5 are removed using HF or the like.

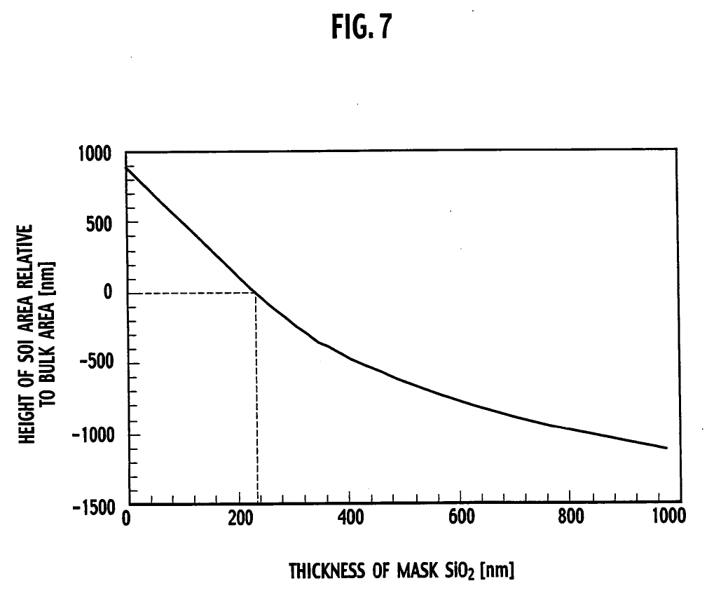

According to the method for manufacturing the semiconductor wafer according to the embodiment of the present invention, it is possible to provide the semiconductor wafer shown in FIG. 1. The thickness of the thermal oxide film 5 in the bulk area can be adjusted by adjust thickness of the first masking film 2 appropriately For example, when forming a thin-film SOI of approximately 100 nm under certain oxygen ion implantation conditions and annealing conditions, as shown in FIG. 7 the optimum thickness of the first masking film 2 is approximately 220 nm, as it prevents a level difference between the SOI area and the bulk area. However, as optimum thickness of the first masking film 2 becomes thinner, as shown in FIG. 3 it may be difficult to stop RIE over etching of the second masking film 3. In this case, it is preferable to introduce a film to serve as a sufficient stopper film in regard to RIE of the second masking film 3, between the second masking film 3 and the first masking film 2. For example, even if the first masking film 2 is an SiO₂ film and has a thickness of several tens of nm and the second masking film 3 is a BSG film and has a thickness of approximately 1000 nm, a SiN film is disposed between the first masking film 2 and the second masking film 3 so that the thickness of the SiN film is approximately 100 nm, and thereby it is possible to stop over-etching of the BSG film as the second masking film 3, with the SiN film. Then, the SiN film in the SOI area is removed selectively with a substance such as phosphoric acid. The side surface of SuN recedes horizontally from the side surface of the BSG film using the isotropic etching. The SiO₂ film of the first masking film 2 in the exposed SOI area is removed selectively with a substance such as BHF acid. The side surface of the first masking film 2 recedes horizontally from the side surface of the BSG film using isotropic etching. Accordingly, it is possible to delineate the second masking film 3 without causing damage to the semiconductor substrate 1.

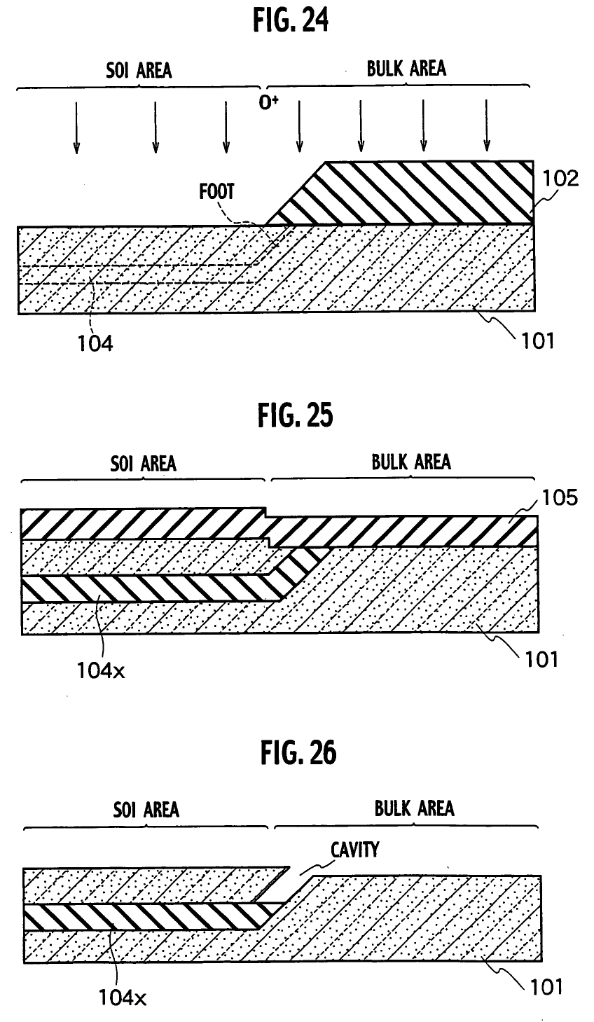

Next, the first comparative example is shown in FIGS. 24 to 26. In the first comparative example, as shown in FIG. 24, the masking film 102 with a sloping side surface is formed on the semiconductor substrate 101 by wet etching or the like. O⁺ is implanted to the semiconductor substrate 101 using the masking film 102 as a mask. As a result, an implantation area 104 is formed in the semiconductor substrate 101 in the SOI area. By forming a slope to the side surface of the masking film 102, the concentration distribution of the oxygen atoms implanted to the semiconductor substrate 101 under the slope shows a profile whereby the end is raised to the surface of semiconductor substrate 101. For this reason, as shown in FIG. 25, a BOX film 104x formed by high temperature annealing and a thermal oxide film 105 are joined together. As a result, great stress is applied to the semiconductor substrate 101, thereby increasing the crystal defects, and deforming the semiconductor substrate 101. Consequently, characteristics of the device are possibly modulated. In addition, when the thermal oxide film 105 is removed after high temperature annealing, a part of the BOX film 104x is removed by over etching. For this reason, as shown in FIG. 26, cavities may form in the boundary between the SOI area and the bulk area, and thereby causing difficulties during forming the device. Consequently, in order to properly form the BOX film 104x at the end of the SOI area, it is necessary to process the side surface of the masking film 102, which serves as a mask during implanting O⁺, into a vertical shape. It is effective to use RIE in order to process the masking film 102 into a vertical shape.

Next, the second comparative example is shown in FIGS. 27 to 29. In the second comparative example, as shown in FIG. 27, a window portion 210 with a vertical sidewall is formed in the SOI area by selectively removing a part of a masking film 202 on a semiconductor substrate 201 by RIE. With the masking film 202 used as a mask, O⁺ is implanted through the window portion 210 to the semiconductor substrate 201. Therefore, an implantation area 204 is formed, which does not raise the end as shown in FIG. 24. However, the semiconductor substrate 201 under the masking film 202 is used as an etching stop layer during RIE. Therefore there exists a risk of crystal defects or contamination caused by RIE damage. Over etching of the semiconductor substrate could also cause variance in the thickness of the SOI layer, or cause deterioration in the flatness of the surface.

By contrast, according to the embodiment of the present invention, a masking film having a multi-layer structure is formed and etching conditions are optimized. As shown in FIG. 3, a part of the second masking film 3 is selectively removed by RIE using the first masking film 2 as an etching stop layer. As a result, a window portion 10 with a vertical sidewall is formed in order to form a flat BOX film 4. Further, as shown in FIG. 4, the first masking film 2 in the SOI area is removed by wet etching instead of RIE. Therefore it is possible to prevent etching damage to the semiconductor substrate 1 by RIE, and to obtain a high degree of flatness for the SOI layer surface.

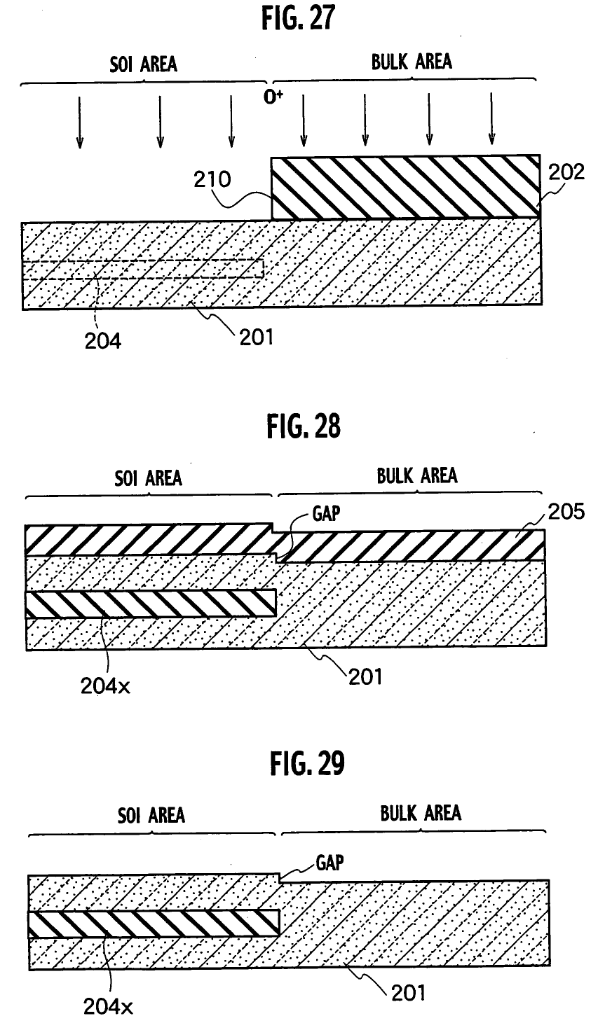

Further, in the second comparative example, the masking film 202 shown in FIG. 27 is removed, and annealed in an oxygen atmosphere. As shown in FIG. 28, the surface level in the SOI area rises higher than the surface level of the bulk area due to volume expansion of the BOX film 204x during high temperature annealing. Consequently, after an oxide film 205 formed by O in the oxygen atmosphere is removed, as shown in FIG. 29, a level difference, between the SOI area and bulk area occurs. As a result, the margin of the lithography process and etching process during device formation is decreased, and yields will be decreased.

By contrast, according to the embodiment of the present invention, as shown in FIG. 6, the first masking film 2 remains in the bulk area during high temperature annealing. Therefore, setting the thickness of the first masking film 2 and oxidization conditions properly, the level of the exposed surface of semiconductor substrate 1 in the SOI area, and the surface underneath the first masking film 2 of semiconductor substrate 1 in the bulk area can be substantially equalized.

Further, in the second comparative example, after implanting O⁺ as shown in FIG. 27 if the thickness of the masking film 202 is reduced to a thickness of approximately 200 nm, in order to control oxidation rate on the surface of the semiconductor substrate 1 in the bulk area, instead of completely removing the masking film 202, before high temperature annealing, it is difficult to detect the end point of etching process of reducing the thickness of the masking film 202. Therefore it is difficult to control the thickness of the remaining film. As a result, after high temperature annealing, the surface level of the exposed surface of the semiconductor substrate 1 in the SOI area and the surface underneath the first masking film 2 of the semiconductor substrate 1 in the bulk area tends to vary. In response to this, according to the embodiment of the present invention, the second masking film 3 shown in FIG. 5 is selectively removed after O⁺ implantation. Therefore, as shown in FIG. 6, the thickness of the first masking film 2 can remain approximately 200 nm without reducing the thickness of the first masking film 2. Therefore the thickness of the first masking film 2 can be controlled to a high degree of precision by the thickness of the first masking film 2 formed at first. Consequently, after high temperature annealing, the level of the exposed surface of the semiconductor substrate 1 in the SOI area and the level of the surface underneath the first masking film 2 of semiconductor substrate 1 in the bulk area can be substantially equalized with each other.

### First Modification

A method for manufacturing a semiconductor device according to a first modification of the embodiment of the present invention will be described referring to FIGS. 1, and 8 to 13.

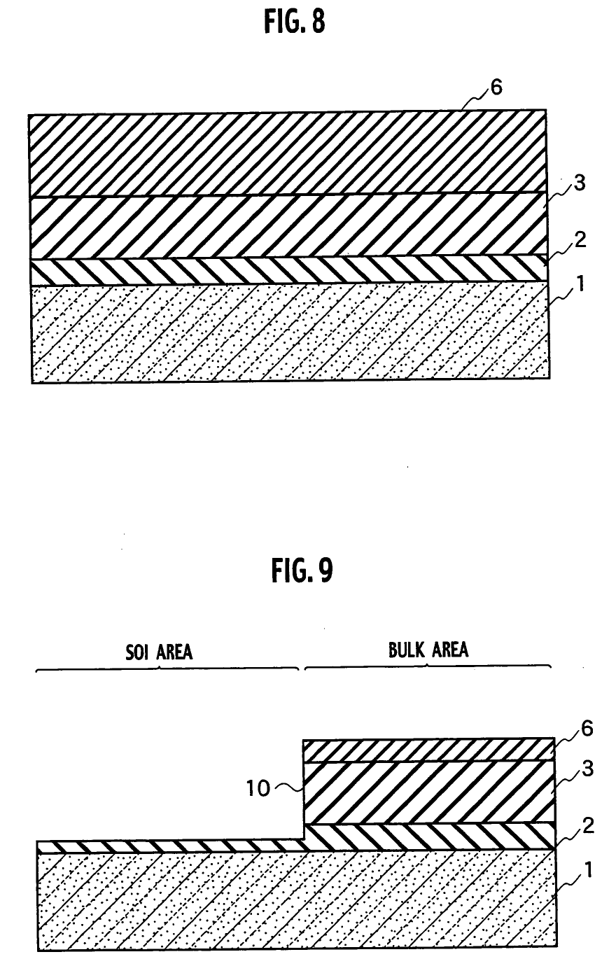

First, as shown in FIG. 8, a first masking film 2, made of SiO₂ or the like is deposited on a semiconductor substrate 1 of Si, using the oxidation or CVD process. A second masking film 3, made of BSG, BPSG or the like, is deposited on the first masking film 2 using CVD or the like so that the thickness of the second masking film 3 is approximately 800 nm. In the first modification, a third masking film 6 made of SiN or the like is deposited on the second masking film 3a so that the thickness of the third masking film 6 is approximately 150 nm.

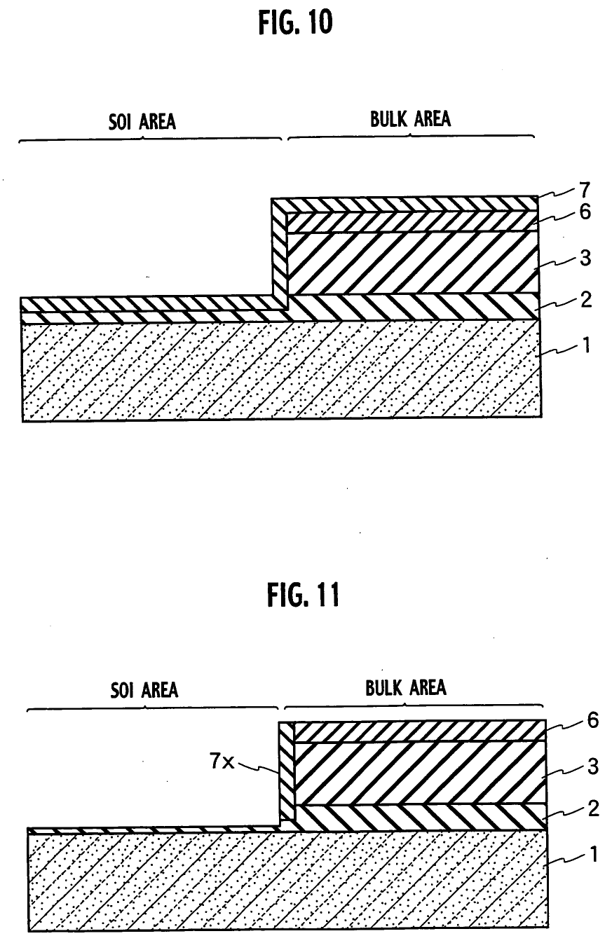

Next, a resist film is coated on the third masking film 6, and then the resist film is patterned by lithography technology. Using the patterned resist film as a mask, the third masking film 6 and the second masking film 3 in the SOI area are selectively removed in sequence by RIE. As a result, a window portion 10 with a vertical sidewall is formed in the SOI area. Here, since first masking film 2 serves as a buffer layer, it is possible to prevent damage to semiconductor substrate 1. The remaining resist film is removed using ashing, sulfuric acid or the like (FIG. 9).

Next, as shown in FIG. 10, an insulating film 7 made of SiN or the like is deposited so as to cover the exposed portions of the first masking film 2, the second masking film 3 and the third masking film 6 by CVD, so that the thickness of the insulating film 7 is approximately 100 nm. Then, the flat part of the insulating film 7 is selectively removed by anisotropy etching such as RIE or the like. As a result, as shown in FIG. 11, a sidewall protection film 7x is formed on the sidewall of the first masking film 2 and the second masking film 3 so that the thickness of the width of the sidewall protection film 7x is approximately 100 nm. At this time, even if the third masking film 6 directly above the second masking film 3 in the bulk area is also over etched, a thickness of approximately 100 nm can be maintained. In other words, the second masking film 3 has a shape surrounded by the first masking film 2, the third masking film 6 and the sidewall protection film 7x.

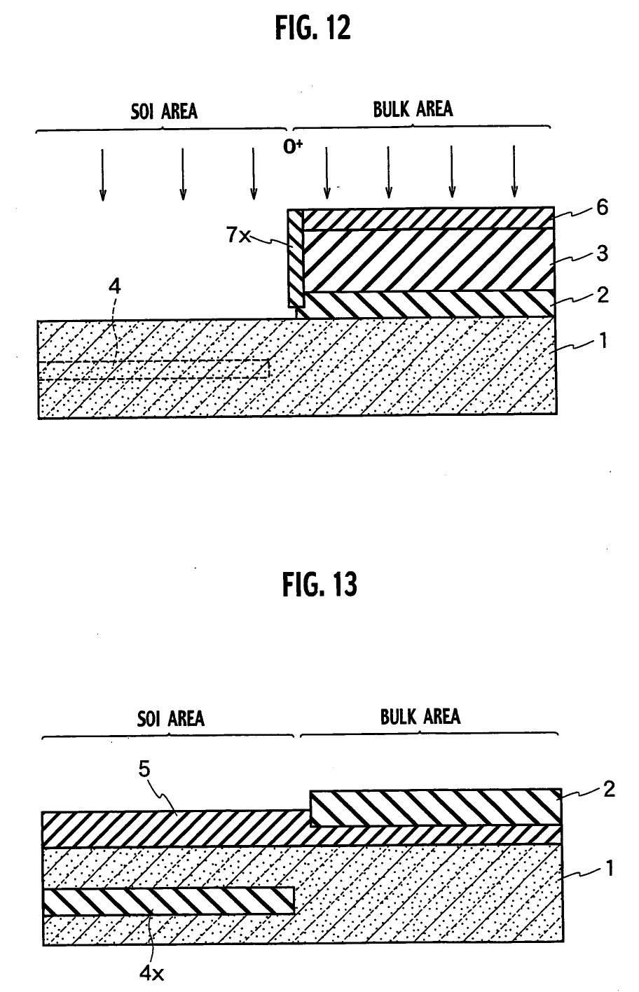

Next, as shown in FIG. 12, the first masking film 2 in the SOI area, made of SiO₂, is selectively removed by wet etching using etching solutions such as HF, BHF or the like or by using HF vapor. At this time, even if the second masking film 3 is an oxidized film system such as BSG or BPSG, it is possible to completely prevent removal of the second masking film 3 by the third masking film 6 and the sidewall protection film 7x. Next, using the first masking film 2, the second masking film 3, the third masking film 6 and the sidewall protection film 7x as masks, the O⁺ which become an oxidizing species is implanted through the window portion 10 to the semiconductor substrate 1 in the SOI area. Thereafter the third masking film 6 and the sidewall protection film 7x are removed using phosphoric acid. Further, the second masking film 3 is removed using HF vapor or the like.

Next, with the first masking film 2 remaining in the bulk area, in an oxygen atmosphere, high temperature annealing is performed at a temperature of approximately 1300 to 1400° C. Using the reaction between the oxidizing species (O) of the implantation area 4 in the SOI area and Si of the semiconductor substrate 1, as shown in FIG. 13, a BOX film 4x is formed in the semiconductor substrate 1. At the same time, the thermal oxide film 5 is formed on the surface of semiconductor substrate 1 in the SOI area and on the surface underneath the first masking film 2 of the semiconductor substrate 1 in the bulk area. Here, by adjusting the thickness of the first masking film 2 in the bulk area, the thermal oxide film 5 is formed so that the surface of the semiconductor substrate 1 in the SOI area and the bulk area is at approximately the same level. Thereafter, the thermal oxide film 5 is removed using HF or the like. Consequently, the semiconductor wafer shown in FIG. 1 can be provided.

In the embodiment of the present invention, if BSG is used as the material for the second masking film 3 and SiO₂ is used as the material for the first masking film 2, the etch selectivity for both the first masking film 2 and the second masking film 3 is not very large. In addition, if SiN is used as the material for the second masking film 3, then the relative stress of SiN is large. Therefore if the SiN film is formed at the necessary thickness as a mask during O⁺ implantation, there is a danger that the stress will cause peeling.

By contract, in the first modification, since the first masking film is removed by using the sidewall protection film 7x to mask the second masking film 3, made of BSG, BPSG or the like, it is possible to prevent removal of the second masking film 3. Further, BSG or BPSG is used for a material for the second masking film 3, for which a large thickness is required. Therefore it is possible to reduce the stress of the masking film and to prevent problems such as peeling and reduction in the process margin.

### Second Modification

A method for manufacturing a second modification of the embodiment of the present invention will be described referring to FIGS. 1, 8 and 14 to 17.

First, as shown in FIG. 8, a first masking film 2 made of SiO₂ or the like is deposited on a semiconductor substrate 1 by the thermal oxidization method, CVD or the like. A second masking film 3 made of BSG or BPSG is deposited on the first masking film 2 by CVD or the like. Further, a third masking film 6 made of SiN or the like is deposited on the second masking film 3a by CVD or the like.

Next, a resist film is coated on the third masking film 6, and then the resist film is patterned by lithography process. Using the patterned resist film as a mask, the third masking film 6 and the second masking film 3 in the SOI area are etched in sequence by RIE or the like so as not to completely remove the first masking film 2 in the SOI area. The remaining resist film is removed by ashing or sulfuric acid or the like. As shown in FIG. 14, as a result, a window portion 10 with a vertical sidewall is formed in the SOI area.

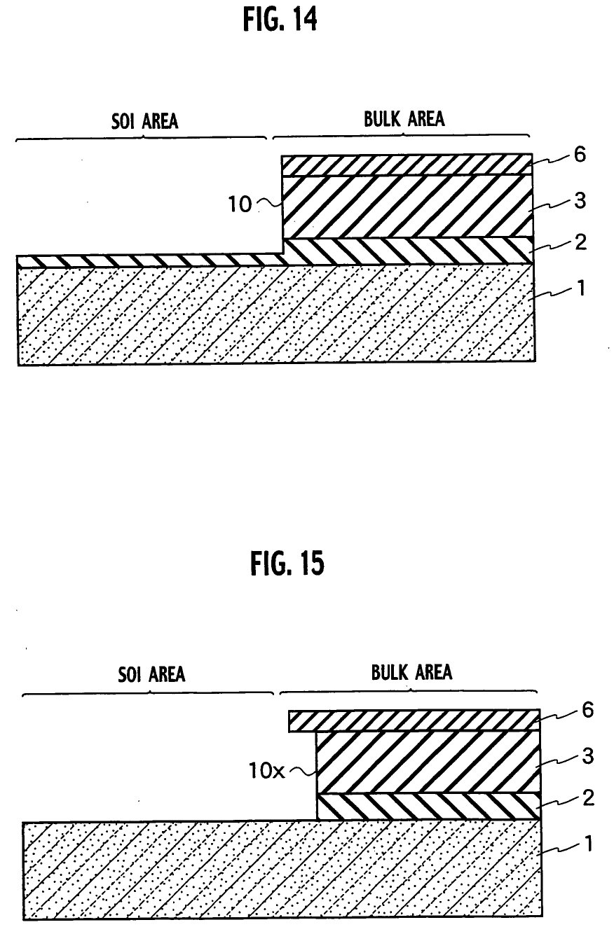

Next, a part of the first masking film 2 in the SOI area is selectively removed using BHF or the like. At this time, as shown in FIG. 15, the first masking film 2 underneath the third masking film 6 and the side surface of the second masking film 3 are also etched and receded laterally. The etching rate of the first masking film 2 and the second masking film 3 can be appropriately controlled respectively by adjusting forming conditions and thermal treatment after formation. The window portion 10x with a vertical sidewall can also be formed. Thereafter, the third masking film 6, which has changed into an overhang shape, is removed using phosphoric acid or the like.

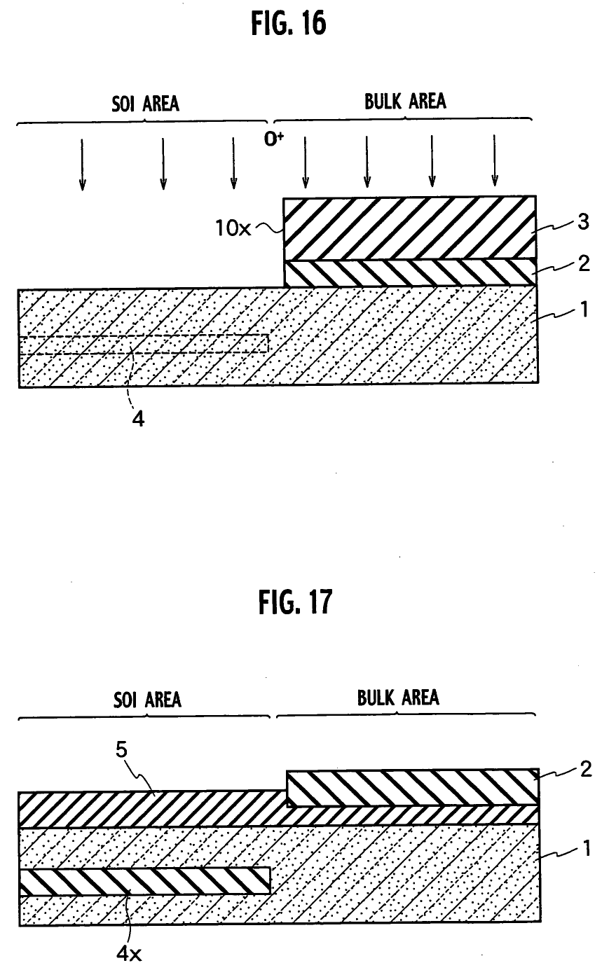

Next, as shown in FIG. 16, using the second masking film 3 as a mask, O⁺ implanted through the window portion 10x to the semiconductor substrate 1 in the SOI area. Then, the second masking film 3 is removed using HF vapor. Then, with the first masking film 2 remaining in the bulk area, in an oxygen atmosphere, high temperature annealing is performed at a temperature of approximately 1300 to 1400° C. By the reaction between the oxidizing species (O) of implantation area 4 in the SOI area and Si of the semiconductor substrate 1, as shown in FIG. 17, a BOX film 4x is formed in the semiconductor substrate 1. In addition, the surface of the semiconductor substrate 1 rises due to the volume expansion of the BOX film 4x. At the same time, a thermal oxide film 5 is formed on the surface of the semiconductor substrate 1. At this time, surface oxidization of the semiconductor substrate 1 because of introducing the oxidizing species (O) into the semiconductor substrate 1 through the first masking film 2 in the bulk area is suppressed. As a result, surfaces in the SOI area and the bulk area are substantially equalized. Thereafter, the thermal oxide film 5 is removed using HF or the like. As a result, as shown in FIG. 1, a hybrid semiconductor wafer without level differences can be provided.

According to the second modification, it is possible to form a thick masking film with an SiO₂ type weak stress film using a process even more simple than the first modification, and to prevent peeling.

Note that in FIG. 15, if it is anticipated that the first masking film 2 and the second masking film 3 can be as a single layer. The simple process enables vertical shape of the side surface of the masking film without damaging the semiconductor substrate 1. At this time, more simply, a resist film can be used as the third masking film 6.

### Third Modification

A method for manufacturing a semiconductor device according to a third modification of the present invention will be described referring to FIGS. 1 and 18 to 21.

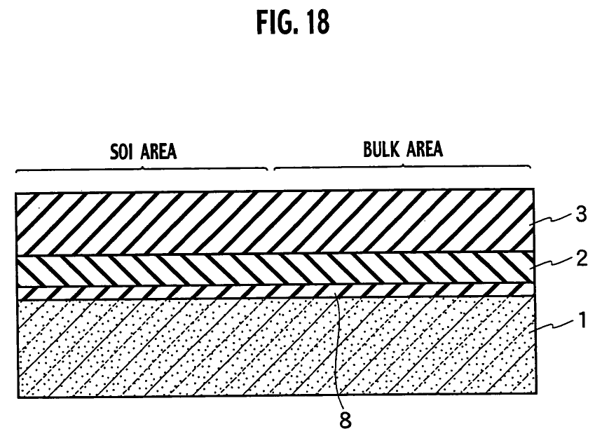

First, a semiconductor substrate 1 is prepared, as shown in FIG. 18. Then, a buffer film 8 made of SiO₂ and the like is formed on the semiconductor substrate 1 by oxidation and the like so that the thickness of the buffer film 8 is approximately 10 nm, so as to protect the semiconductor substrate 1 from damage when patterning in masking films later processes. A first masking film 2 made of polycrystalline Si, amorphous Si or the like, which has the characteristics of blocking the diffusion of oxidizing species such as O, is deposited by CVD or the like. At this time, the thickness of the first masking film 2 is adjusted so as to correspond to the amount of SiO₂ which should be removed in the bulk area. For example, if the oxidation should be reduced by the thickness of approximately 100 nm, the thickness of the first masking film 2 should be adjusted to approximately 45 nm. As a result, the oxidation of Si in the semiconductor substrate 1 in the bulk area will be prevented until the polycrystalline Si or amorphous Si as the first masking film 2 is fully oxidized. A second masking film 3 made of BSG or BPSG is deposited on the first masking film 2 by CVD or the like so that the thickness of the second masking film 3 is approximately 1000 nm. Although a single-layer film is used as the second masking film 3, it is acceptable to use composite films.

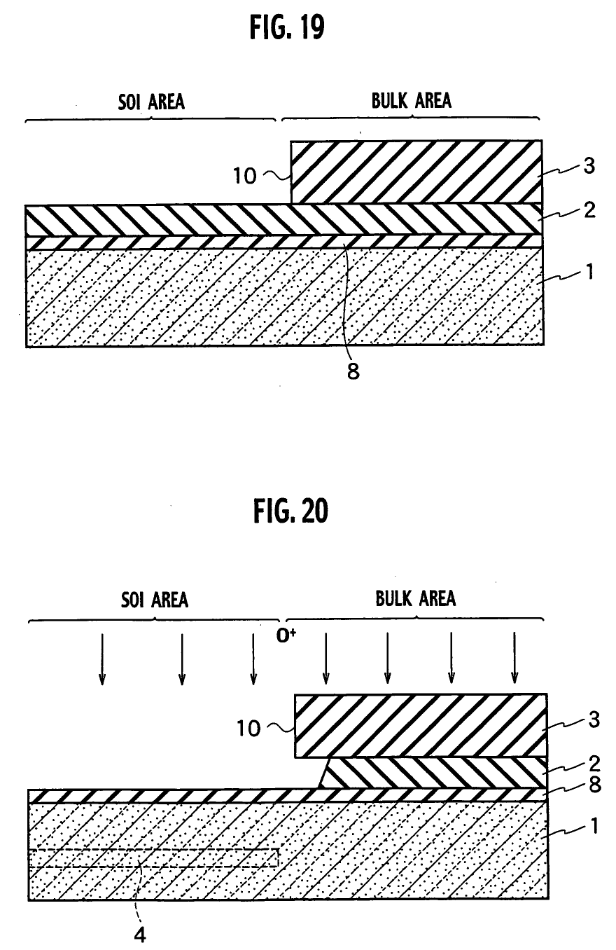

Next, a resist film is coated on the second masking film 3, and then the resist film is patterned by lithography process. Using the patterned resist film as a mask, the second masking film 3 in the SOI area is selectively removed by RIE or the like. As a result, a window portion 10 having perpendicular sidewalls in the SOI area is formed. Since the first masking film 2 is made from polycrystalline Si, amorphous Si and the like, a process margin can be secured because the first masking film 2 can be used as a layer to stop RIE on the second masking film 3. The remaining resist film is removed by the use of ashing or sulfuric acid filtrate solution or the like, as shown in FIG. 19. Subsequently, the first masking film 2 in the SOI area is selectively removed by chemical etching (CDE) or the like. Otherwise, if the first masking film 2 is polycrystalline Si, amorphous Si and the like, it is possible to delineate the first masking film 2 by RIE, with the buffer oxide film 8 as an etching stopper. If necessary, the buffer oxide film 8 may be removed.

Next, as shown in FIG. 20, using the second masking film 3 as a mask, O⁺, which become oxidizing species, is implanted through the window portion 10 to the semiconductor substrate 1 in the SOI area. Subsequently, the second masking film 3 is removed by the use of HF or the like. Then, high temperature annealing is done in an oxidizing ambient at approximately 1300 to 1400° C. A BOX film 4x is formed in the semiconductor substrate 1 in the SOI area by the reaction between the oxidizing species (O) of the implantation area in the SOI area and the Si of the semiconductor substrate 1. At this time, the surface of the semiconductor substrate 1 in the SOI area expands due to volume expansion of the BOX film 4x. Further, the thermal oxide film 5 is formed on the surface of the semiconductor substrate 1. In the bulk area, oxidation of the surface of the semiconductor substrate starts only after the first masking film 2 of a single crystal Si, amorphous Si and the like is completely oxidized and becomes SiO₂. Accordingly, oxidation of the surface of the semiconductor substrate 1 in the bulk area is limited. Subsequently, the thermal oxide film 5 is removed and the semiconductor wafer is provided shown in FIG. 1.

In the embodiment of the present invention, remaining the first masking film 2 that permits diffusion of the oxidizing species, to restrain the surface oxidation in the bulk area, corresponding to the expansion in the SOI area due to the formation of a BOX film 4x. By contrast, according to the third modification, it is possible to limit surface oxidation in the bulk area, even when using the material of polycrystalline Si, amorphous Si or the like having characteristics of reducing diffusion of the oxidizing species as the first masking film 2. Therefore it is possible to control the horizontal level of the semiconductor substrate 1 by adjusting the thickness of the first masking film 2.

### Fourth Modification

A method for manufacturing a semiconductor device according to a fourth modification of the present invention will be described referring to FIGS. 1, 18 to

First, as shown in FIG. 18, a buffer film 8 made of SiO₂ or the like is deposited on the semiconductor substrate 1 by CVD, oxidation or the like so that the thickness of the buffer film 8 is approximately 50 nm, if needed. A first masking film 2 of SiN or the like, which has the characteristics of reducing diffusion of the oxidizing species such as O, is deposited by CVD or the like so that the thickness of the first masking film 2 is approximately 150 nm. A second masking film 3 made of BSG, BPSG or polysilicon is deposited on top of the first masking film 2 by CVD or the like so that the thickness of the second masking film 3 is approximately 1000 nm.

Next, a resist film is coated on the second masking film 3, and then the resist film is patterned by lithography process. Using the patterned resist film as a mask, the second masking film 3 in the SOI area is selectively removed by RIE or the like to form a window portion 10 that has perpendicular sidewalls in the SOI area. Since at this time it is possible to use the first masking film 2 as an RIE etching stop layer for the second masking film 3, it is possible to prevent damages to the semiconductor substrate due to RIE and ensure process margins. The remaining resist film is removed using ashing, sulfuric acid filtrate solution or the like, as shown in FIG. 19.

Next, the first masking film 2 in the SOI area is removed so as to not stick out from the edges of the second masking film 3, by using H₃PO₄ or the like. If needed, the buffer film 8 is removed using HF or the like. Then, as shown in FIG. 20, using the second masking film 3 as a mask, O⁺, which become an oxidizing species is implanted through the window portion 10 to the semiconductor substrate 1 in the SOI area. Afterward, the second masking film 3 is removed by use of HF vapor or the like.

Then, high temperature annealing is performed in an oxidizing ambient at a temperature approximately from 1300 to 1400° C. By the reaction between oxidizing species (O) of the implantation area in the SOI area and the Si of the semiconductor substrate 1, a BOX film 4x is formed in the semiconductor substrate 1 in the SOI area. At this time, because of the presence of the first masking film 2 made of SiN or the like, which has characteristics of inhibiting diffusion of oxidizing species from the ambient to the surface of the semiconductor substrate 1 of the bulk area, oxidation of the surface of the semiconductor substrate 1 in the bulk area is inhibited. Here, by adjusting annealing conditions so that the conditions allow the amount of the semiconductor substrate expanding due to the BOX film 4x in the SOI area to match up the amount receding due to surface oxidation, it is possible to substantially equalize the horizontal levels of the surfaces of the semiconductor substrate 1 in the SOI area and the bulk area Afterward, the thermal oxide film 5 of the semiconductor 1 is removed, and a semiconductor wafer shown in FIG. 1 is provided.

According to the fourth modification of the present invention, the expanded amount due to the BOX film formation 4x in the SOI area and the receding amount due to surface oxidation of the semiconductor substrate 1 in the SOI area are adjusted to be equal to each other, and surface oxidation of the semiconductor substrate 1 is prevented at the bulk area. As a result, it is possible to substantially equalize the surface level of the semiconductor substrate 1 of each the SOI area and the bulk area.

### Fifth Modification

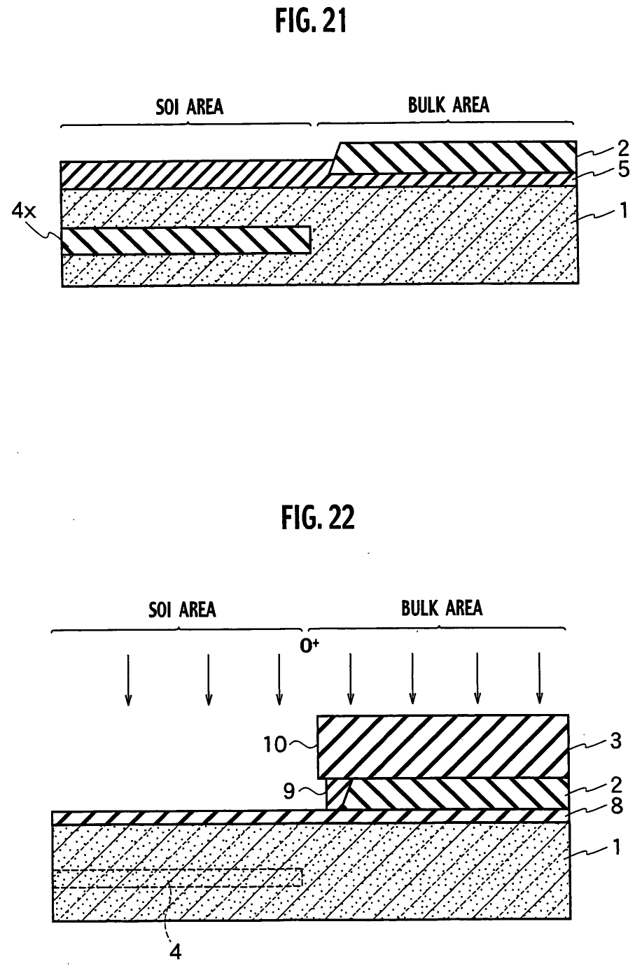

In a method for manufacturing a semiconductor wafer according to the fifth modification of the embodiment of the present invention, the procedures of FIGS. 18 to 20 are substantially identical to the fourth modification, so redundant explanation has been omitted. In the fifth modification, as shown in FIG. 20, after etching back the first masking film 2 to underneath the second masking film 3, an insulating film such as poly crystalline Si, SiN or the like is deposited, which reduces the supply of oxidizing species to the semiconductor substrate 1. Then, a part of the insulating film is selectively removed using CDE, RIE or the like. For example, as shown in FIG. 22, a buried buffer film 9, is easily buried underneath the second masking film 3 adjoining the first masking film 2 by using CDE. Thereafter, an O⁺, which become to oxidizing species is implanted to the semiconductor substrate 1 in the SOI area. At this time, with an implant the buried buffer film 9, the supply of oxidizing species to the boundary in the SOI area and bulk area can be reduced in self-aligned manner.

At the boundary in the SOI area and bulk area, the BOX film 4x is formed to be too thick in parts. According to the fifth modification, by forming the buried buffer film 9 to suppress the supply of oxidizing species to the boundary, it is possible to suppress the supply of oxidizing species to the boundary in self-aligned manner. Consequently, the increase in thickness of the BOX film 4x can be restrained. In addition, the buried buffer film 9 also contributes to suppress of oxidization of the semiconductor substrate 1 in the boundary. Therefore even if the thickness of the BOX film 9 increases to some extent, the vanishing of the SOI layer can be avoided.

### Other Embodiments

In the embodiment of the present invention, by forming plural masking film structures with different boundary structures within the semiconductor wafer by using lithography process, it is possible to form multiple boundaries of different shapes, such as boundaries where the BOX film 4x and the thermal oxide film 5 are separated, and boundaries where the BOX film 4x and the thermal oxide film 5 are not separated.

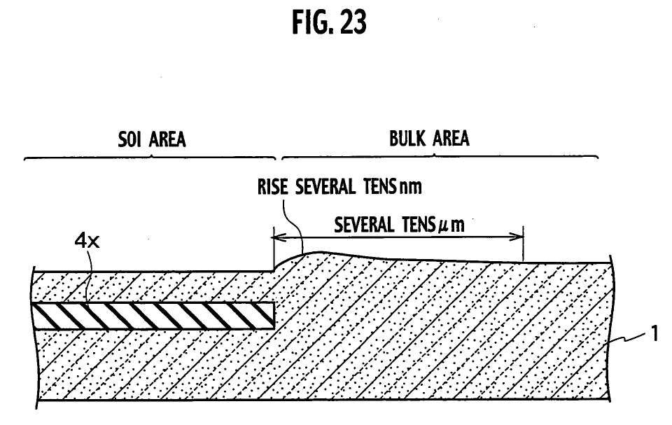

In addition, in patterned SIMOX technology, when forming the BOX film 4x, a strong stress to the bulk area can be generated, resulting in the danger of negative effects occurring on elements over a wide area. However, due to appropriate forming conditions, during high temperature annealing the surface height of the bulk area is deformed so there is a slight change from the boundary to an area several tens of μm away. This enables to release stress of a patterned SIMOX substrate. As shown in FIG. 23, if bulk surface is raised in several tens of nm height within a width of several tens of μm, it is difficult for problems to arise within element formation. However, even this kind of slight rise can cause problems. In this case, it would be applicable to set the thickness of the masking films so that the surface level of the semiconductor substrate I in the SOI area (namely the surface level of the SOI layer) is in the middle height of a rising sections of the bulk area. Further, as an example, if the structure of the mask material (masking film) is changed within the boundary range of approximately several tens of μm, conditions can be set to promote oxidization of the semiconductor substrate 1. Alternatively, annealing could be performed after several tens of nm thick have been removed from the semiconductor substrate 1 in the boundary area of approximately several tens of μm in advance. If there are no problems in terms of damage and contamination, an over etching of the first masking film 2 up to the semiconductor substrate 1 in a condition where etching rate in areas near to the pattern boundary is large can be performed in RIE of the first masking film 2. Therefore, it is possible to easy to handle without having to change other structures.

Various modifications will become possible for those skilled in the art after receiving the teachings of the present disclosure without departing from the scope thereof.

What is claimed is:

1. A method for manufacturing a hybrid semiconductor wafer having a buried oxide film, comprising:
depositing a first masking film on a silicon based substrate;
depositing a second masking film on the first masking film;
forming a window portion having a perpendicular sidewall by selectively removing a part of the second masking film;
removing a part of the first masking film selectively using the second masking film as a mask;
implanting oxidizing species into the substrate through the window portion using the first masking film and the second masking film as masks;
removing the second masking film; and
forming a buried oxide film in the substrate by reaction between the oxidizing species and the silicon, and forming a thermal oxide film in the substrate, by annealing in an oxidizing ambient.

2. The method of claim 1, wherein forming of the thermal oxide film comprises, suppressing oxidation of a surface of the substrate underneath of the first masking film more than oxidation of an exposed surface of the substrate.

3. The method of claim 1, wherein forming of the window portion comprises, removing a part of the second masking film using the first masking film as an etching stop layer.

4. The method of claim 1, wherein removing of the part of the first masking film comprises, wet etching a part of the first masking film.

5. The method of claim 1, wherein the first masking film permits penetration of the oxidizing species in the oxidizing ambient.

6. The method of claim 5, wherein the first masking film is a silicon oxide film.

7. The method of claim 1, wherein the first masking film reduces penetration of the oxidizing species in the oxidizing ambient.

8. The method of claim 7, wherein the first masking film includes material selected from one of single-crystalline silicon, amorphous silicon and silicon nitride.

9. The method of claim 1, wherein the second masking film includes material selected from one of borosilicate glass and boron phosphorous silicate glass.

10. The method of claim 1, further comprising: forming a third masking film on the second masking film, before forming of the window portion.

11. The method of claim 10, wherein forming of the window portion comprises, removing a part of the third masking film selectively.

12. The method of claim 11, further comprising: forming a sidewall protection film on the first masking film so as to adjoin a sidewall of the second and third masking films, after removing of the part of the third masking film.

13. The method of claim 12, wherein forming of a part of the first masking film comprises, removing a part of the first masking film using the third masking film and the sidewall protection film as masks.

14. The method of claim 11, further comprising: removing each parts of the first masking film and second masking film underneath the third masking film, after the removing of the part of the third masking film.

15. The method of claim 10, wherein the third masking film comprises silicon nitride.

16. The method of claim 1, further comprising: depositing a buffer film on the substrate, before depositing the first masking film.

17. The method of claim 1, wherein forming of the thermal oxide film comprises, forming the thermal oxide film on an exposed surface of the substrate with a thickness equal to the thickness increased due to volume expansion of the BOX film.

18. The method of claim 1, wherein removing the part of the first masking film comprises, further removing another part of the first masking film underneath the second masking film.

19. The method of claim 18, further comprising: burying a buried buffer film underneath the second masking film to adjoin the first masking film, after the removing of the part of the first masking film underneath the second masking film.

20. The method of claim 19, wherein the oxidizing species are implanted through a mask implemented by the buried buffer film.
